(19) United States
(12) Patent Application Publication
(10) Pub. No.: US 2009/0289039 A1
(43) Pub. Date: Nov. 26, 2009

(54) Circuit board conveying and soldering apparatus

(75) Inventors: Kazuhide Takahashi, Kosai (JP); Kimitoshi Makino, Kosai (JP); Takafumi Toda, Kosai (JP)

Correspondence Address: EDWARDS ANGELL PALMER & DODGE LLP, P.O. BOX 55874, BOSTON, MA, 02205, US

(73) Assignee: Yazaki Corporation, Tokyo (JP)

(21) Appl. No.: 12/453,407

(22) Filed: May 11, 2009

(30) Foreign Application Priority Data
May 21, 2008 (JP) 2008-132827

(51) Int. Cl. B23K 1/005; H05K 3/34

(52) U.S. Cl. 219/85.12; 219/388; 219/405; 219/411

(57) ABSTRACT

A circuit board and components provided thereupon are held by and between lower and upper palettes. The upper palette has protecting portions that are provided above and opposed to the components. The shielding components prevent light beams irradiated by a preheating light source from directly reaching the components made of colored synthetic resin. Meanwhile, the upper palette has openings that are opposed to the circuit board except for the components protected by the protecting portions members. The light beams from the light source travel through the openings and applied to the circuit board. Openings are formed so as to be opposed to terminals that are soldered on and connected to the circuit board. Inner surfaces of the openings are made of light-reflecting material that reflects downward the light beams from the light source.

### CROSS REFERENCE TO RELATED APPLICATION

The priority application Japan Patent Application No. 2008-132827 upon which this patent application is based is hereby incorporated by reference.

### BACKGROUND OF THE INVENTION

1. Field of the Invention

The present invention relates to a conveying-soldering apparatus that feeds a circuit board and electrical and/or electronic components to a heating step for providing soldered connection of the circuit board and the components.

2. Description of the Related Art

FIG. 5A shows a conventional circuit board soldering step. FIG. 5B shows a conventional conveying-soldering apparatus (see for example Japanese Patent Application Laid-Open Publication S62-144876).

The soldering step (soldering device) shown in FIG. 5A includes a plurality of circuit boards 52 arranged at regular pitches upon a chain conveyer 51, a pair of far-infrared heaters 53 for preheating, which are arranged above and underneath the chain conveyer 51 in a feeding direction B of the circuit boards 52, respectively, a pair of far-infrared heaters 54 for isothermal heating, a pair of near-infrared heaters 55 for rapid heating (solder reflow process), and a cooling fan 56. As shown in FIG. 5B, front and rear ends of the circuit board 52 rest on the conveying-soldering apparatus 57, and the conveying-soldering apparatus 57 is placed on the chain conveyers 51.

The circuit board 52 at an ambient temperature is heated in the preheating step (53). In an isothermal heating step (54), the circuit board 52 is kept at a constant temperature. In a rapid heating (55), the circuit board 52 is heated to not less than 200° C., so that cream solder (not shown) upon the printed circuit (land) is melted and the components 58 on the circuit board is soldered and connected to the printed circuit 52 and cooled by the fan 56 (see FIGS. 3 and 4 of Japanese Patent Application Laid-Open Publication S62-144876).

### SUMMARY OF THE INVENTION

FIGS. 6A to 6C show a conventional circuit board soldering step. In the soldering step (soldering device), by virtue of a conveying-soldering apparatus 32 made of synthetic resin and composed of an upper palette 31 and a lower palette 3 (see FIG. 6A), flux 33 is applied (sprayed) upon a lower surface 2a of a circuit board 2 while the circuit board 2 and components 5 to 8 on the circuit board 2 are held. Next, as shown in FIG. 6B, the circuit board 2 is preheated both from above and from below (preheating units 16 and 34). Further, as shown in FIG. 6C, the lower surface 2a of the circuit board 2 is immersed in a solder flow tub 35 and a molten solder is applied to terminal connecting portions (i.e., lands and throughholes) of the printed circuit 2 with a jet pressure 35a, so that the terminals 11 of the components 5 to 8 are soldered on and connected to the circuit board 2 (soldered connection 11a).

In the conveying-soldering apparatus 32 shown in FIG. 6A, the circuit board 2 is placed on the lower palette 3 and the upper palette 31 is attached to the lower palette 3 from above in such a manner that the circuit board 2 is covered by the upper palette 31. The components 6 to 8 are pressed by a spring force of a pressing member 15 of the upper palette 31 and attached on the circuit board 2 so as to resist the jet pressure 35a of the solder flow 35 (see FIG. 6C).

The lower palette 3 has a large opening 26 such that the circuit board 2 is exposed to an outside. The solder jet 35a occurs within the opening. The upper palette 31 has a plurality of openings 37 so that a weight of the upper palette 31 is reduced. The lower palette 3 and the upper palettes 31 are secured to each other for example through snap fit by a locking portion (not shown).

The flux 33 shown in FIG. 6A is a solvent for use in removing surface oxide formed upon a joint surfaces of the terminals 11 and 13 of the components 5 to 8 and the land of the circuit board 2. The circuit board 2 is preheated to a temperature of about 100° C. to 120° C. at which the flux 33 on the circuit board surface 2a is activated. The purpose of the preheating is to improve finish and wettability of soldering.

Preheating of the upper surface 2b of the circuit board 2 shown in FIG. 6B is performed using thermal radiation of the light source 16 at a temperature of about 400° C. Preheating of the lower surface 2a is performed by applying warm air 34. The circuit board 2 is delivered integrally with the conveying-soldering apparatus 32 to the steps shown in FIGS. 6A to 6C in that order by the conveyer or other conveying means. The components 5 to 8 are soldered on and connected to the circuit board 2 to form a circuit board assembly 38.

The soldering steps shown in FIGS. 6A to 6C has a drawback. For the sake of improved manufacturing efficiency, preheating time may be shortened using a higher preheating temperature (by increasing the thermal radiation of the upper light source 16). As a result, components made of colored synthetic resin may be damaged due to higher temperature when a light 16a irradiating downward from the light source 16 (in the preheating step of FIG. 6B), is applied via the palette-weight-reducing opening 37 to the colored-resin components such as connector housings 5 to 7 and relays (not shown), which have high light and heat absorption property.

In view of the above-identified drawback, an object of the present invention is to provide a conveying-soldering apparatus that feeds a circuit board for soldered connection of components to the circuit board, the apparatus being capable of preheating the circuit board effectively and improving manufacturing efficiency of a circuit board assembly in such a manner that the components hade of colored synthetic resin on the circuit board are not damaged by high temperature under high thermal radiation even when the preheating temperature for the circuit board is increased.

In order to attain the above-identified objectives, a circuit board conveying-soldering apparatus according to one embodiment of the present invention includes (a) a preheating light source that emits a light beam downward for preheating of a circuit board and components provided thereupon, (b) a lower palette on which the circuit board and the components provided thereupon are placed, and (c) an upper palette that is provided beneath the light source and above the lower palette and is configured to hold the circuit board and the components provided thereupon placed on the lower palette. Further, the upper palette includes a protecting portion that is opposed to a region of the circuit board on which a colored-resin component is provided and is configured to prevent a light beam of the preheating light source from directly reaching the colored-resin component on the circuit board, and a plurality of openings that is opposed to a region of the circuit board on which no colored-resin component is provided and is configured to allow the light beam of the preheating light source to directly reach the region of the circuit board on which no colored resin-component is provided.

With the construction and arrangement described above, the colored-resin components on the circuit board is partly covered by the upper palette and protected from light and heat of the light source, so that the damage to and deformation of the colored-resin component is effectively prevented. Also, the circuit board side except for the colored-resin components is exposed to the light source via the openings of the upper palette, and the light and heat of the light source is directly applied to the circuit board side via the openings, and accordingly the soldered connection between the circuit board and the components can be performed smoothly and effectively.

With the higher temperature (output) of the light source than in conventional devices, the circuit board can be effectively preheated in a shorter time. Also, the entire circuit board except for the colored-resin components are directly preheated by the light source and the soldered connection between the circuit board and the components can be performed smoothly and effectively. The solderability (property of connection by soldering) of the components to the circuit board and manufacturing efficiency of the circuit board assembly are improved.

Note that the term “circuit board side” refers to an entirety of the circuit board and terminals and components provided thereupon. Also, the term “component” in its broadest sense may refer to various components provided on the circuit board, such as the colored-resin component, a component made of low light-and-heat-absorbent synthetic resin, and various types of terminals.

Preferably, at least one of the openings of the upper palette registers with a terminal that is soldered on and connected to the circuit board. When the terminals on the circuit board are exposed to an outside via the opening of the upper palette, the light beam of the light source can be directly applied to the terminal via the opening. Accordingly, the terminal is preheated with the circuit board connecting portion of the terminal heated as appropriate, and thus the soldered connection between the circuit board and the components can be achieved smoothly and effectively. Note that it is not mandatory that the opening register with (or be opposed to) the circuit board connecting portion of the terminal (i.e., the circuit board is placed directly beneath the opening). The opening may face a body of the terminal as a distal end of the terminal opposed to the circuit board connecting portion thereof (in this case, it is possible that the circuit board is not exposed to a region beneath the opening). The advantage of the present invention with the basic configuration is bolstered by directly preheating the circuit board by the light source, and at the same time directly or indirectly preheating the terminal connecting portion of the circuit board.

Preferably, in the circuit board conveying-soldering apparatus of the present invention, the opening may be opposed to terminals that are guided out of a connector housing as the colored-resin component.

With the construction and arrangement described above, the terminal guided out of the connector housing is directly preheated by the light and heat of the light source along with the circuit board portion in the neighborhood thereof, and the soldered connection between the terminal and the circuit board can be achieved smoothly and effectively. The terminal is curved in an L shape. The connector housing is covered by the upper palette and is protected from the light source.

Preferably, the circuit board conveying-soldering apparatus of the present invention may have at least one opening that is opposed to a terminal for connecting an electrical component such that the bus bar integral with the terminal is solder connected to the circuit board.

With the construction and arrangement described above, the terminal for use in connecting the electrical component is exposed to an outside via the opening, and the terminal for connecting the electrical components are directly preheated by the light beam of the light source, and the bus bar of the terminal is also heated by heat transfer, and thus the soldered connection between the bus bar and the circuit board can be performed smoothly and effectively.

Preferably, the circuit board conveying-soldering apparatus of the present invention may have the opening opposed to the bus bar. When the bus bar of the terminal is exposed to an outside via the opening and the bus bar is directly heated by the light beam of the light source via the opening, and thus the soldered connection between the bus bar and the circuit board can be performed more smoothly and effectively.

Preferably, in the circuit board conveying-soldering apparatus, at least the inner surface of the opening may be formed of a material that reflects the light emitted by the light source to an oblique and downward direction toward the circuit board. By virtue of the light reflecting inner surface, not only are the circuit board and the terminals directly preheated by the direct incoming light beam from the light source, but also preheated by the light beam reflected off the inner surface downward, and thus the preheating time can be shortened and thus the manufacturing efficiency of the circuit board assembly can be further improved.

Also, it is possible to form the entire upper palette of the light-reflecting material. Since it is not necessary to provide the inner surface of the opening with special treatment, the upper palette including an inner surface of the opening can be readily made with low manufacturing cost. Aluminum is suitable as a light-reflecting material.

### BRIEF DESCRIPTION OF THE DRAWINGS

These and other objects, features, and advantages of the present invention will become more apparent upon reading of the following detailed description along with the accompanied drawings, in which:

FIG. 1 is a partially cross-sectional front elevation of a conveying-soldering apparatus according to a first embodiment of the present invention.

FIG. 2 is a plan view of the conveying-soldering apparatus and a circuit board according to the first embodiment of the present invention.

FIG. 3 is a plan view of the circuit board shown in FIG. 2.

FIG. 4 is a front elevation of the conveying-soldering apparatus according to a second embodiment of the present invention.

FIG. 5A schematically shows a conventional circuit board soldering step.

FIG. 5B is a front elevation of a conventional circuit board conveying-soldering apparatus.

FIG. 6A is a partially cross-sectional front elevation of a conventional circuit board conveying-soldering apparatus.

FIG. 6B shows a preheating step performed by the conventional circuit board conveying-soldering apparatus shown in FIG. 6A.

FIG. 6C shows a soldering step performed by the conventional circuit board conveying-soldering apparatus shown in FIG. 6A.

### DESCRIPTION OF THE PREFERRED EMBODIMENTS

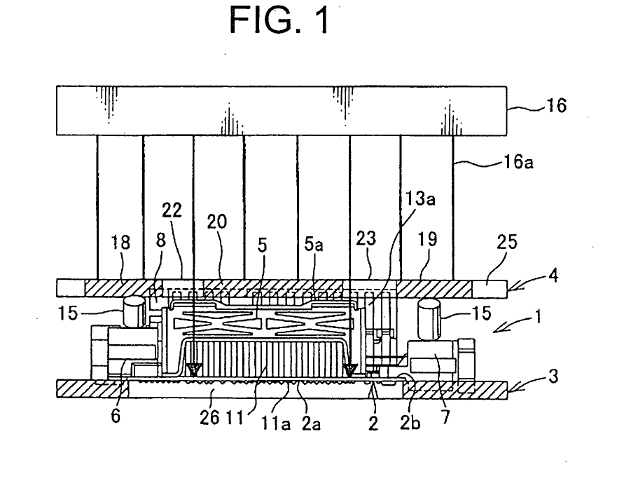

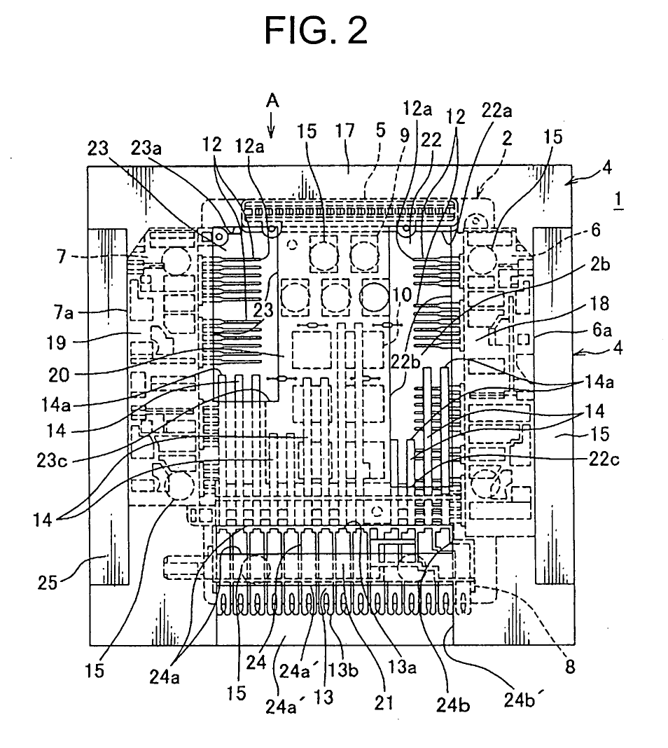

A circuit board conveying-soldering apparatus according to a first embodiment of the present invention is described below with reference to FIGS. 1 to 3. FIGS. 1 and 2 show the circuit board conveying-soldering apparatus and a method of preheating effectuated by the conveying-soldering apparatus according to the first embodiment of the present invention.

As shown in FIG. 1, a circuit board conveying-soldering apparatus 1 includes (a) a plate-shaped lower palette 3 made of synthetic resin, upon which a circuit board 2 is placed, and (b) a plate-shaped upper palette 4 made of synthetic resin and having spring-biased pressing members 15 that presses components 5 to 10 against the circuit board 2.

As shown in FIG. 2, the upper palette 4 includes protecting portions 17 to 20 (that covers colored-resin components 5, 6, 7, 9, and 10 (i.e., the components made of colored synthetic resin) and prevents radiation of light and heat of a light source 16 from directly reaching the colored-resin components 5, 6, 7, 9, and 10.

The upper palette 4 also has a plurality of openings 22 to 24 that let the heat and light emitted by the light source 16 reach terminals 12 and 13 made of conductive metal and a circuit board connecting portion 14a of a bus bar 14. The light source 16 is for use in preheating for soldering (see FIG. 1).

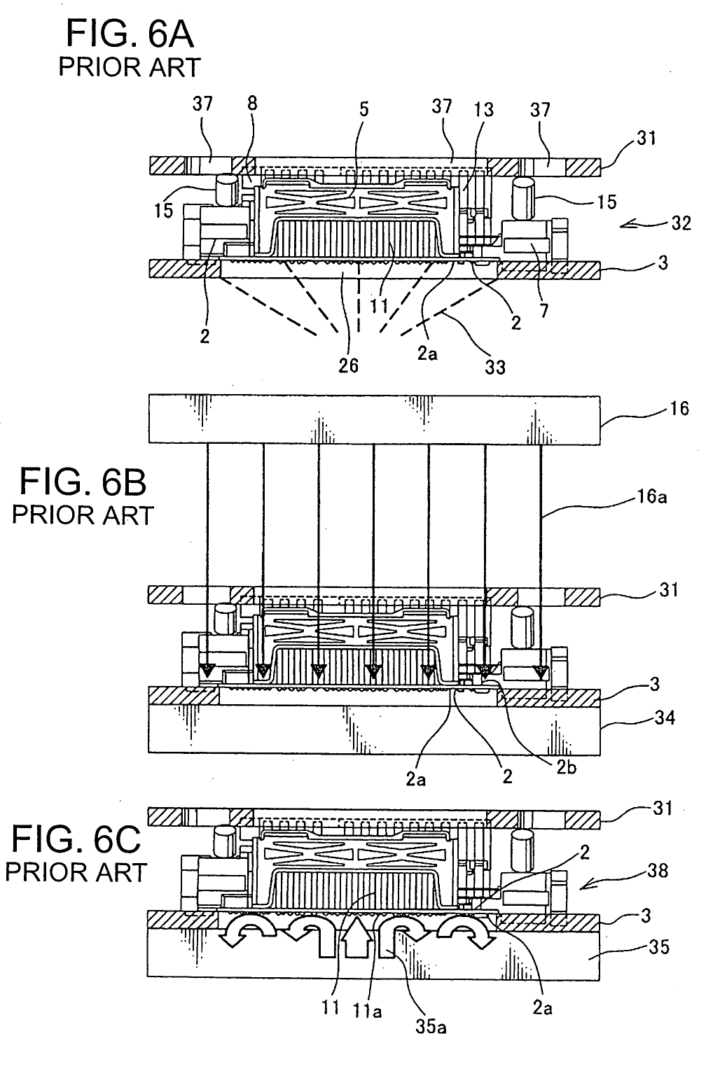

The lower palette 3 shown in FIG. 1 is a known component used in a conventional circuit board conveying-soldering apparatus as shown in FIG. 6. The lower palette 3 includes a large opening 26 through which a jet of the solder flow is applied to an underside (i.e., a surface to be soldered) 2a of the circuit board 2. The upper palette 4 shown in FIG. 2 differs from the upper palette of the conventional circuit board conveying-soldering apparatus shown in FIGS. 6A to 6C in that the openings 22 to 25 are provided with different sizes and at several different locations than those of the apparatus shown in FIGS. 6A to 6C. The lower palette 3 and the upper palettes 4 are engageable with each other through snap fit by a locking member (not shown) in a manner that the circuit board 2 and the components 5 to 14 are held between the two palettes.

Referring to FIG. 6B showing the conventional apparatus, preheating of the underside of the circuit board 2 is performed by hot air or warm air. In contrast, in the conveying-soldering apparatus shown in FIG. 1, the preheating of the lower-side can be omitted and the preheating can be made solely using the light source 16 depending upon the size of the circuit board 2 and arrangement of the colored-resin components 5 to 7, 9, and 10. The pressing member 15, the circuit board 2, the components provided on the circuit board are such known components as shown in FIGS. 6A to 6C.

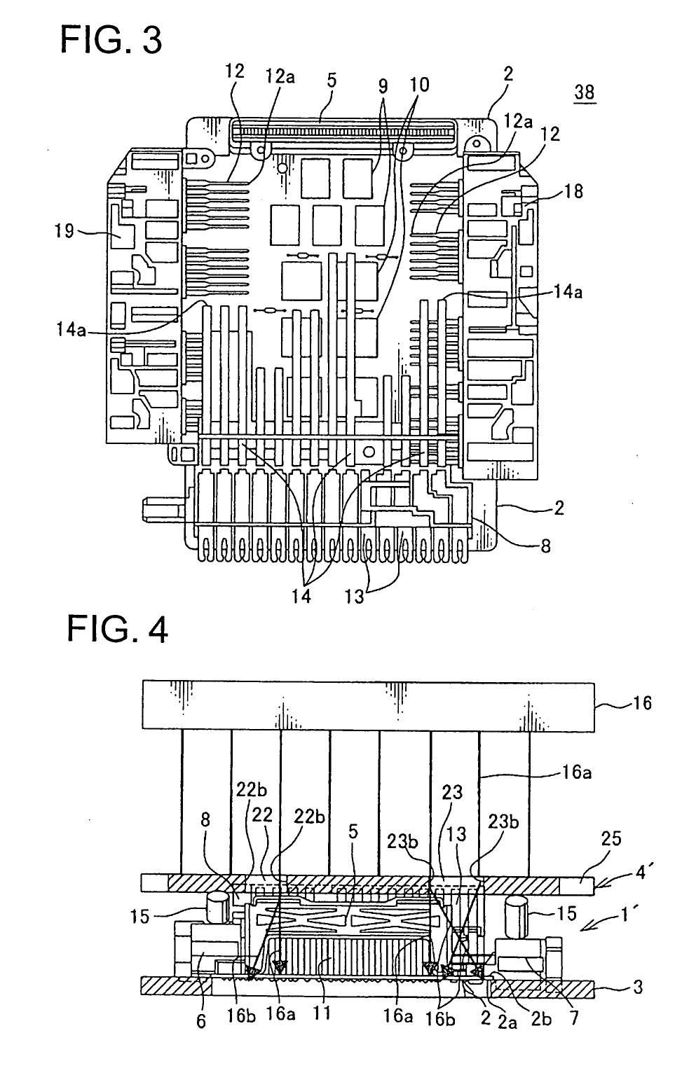

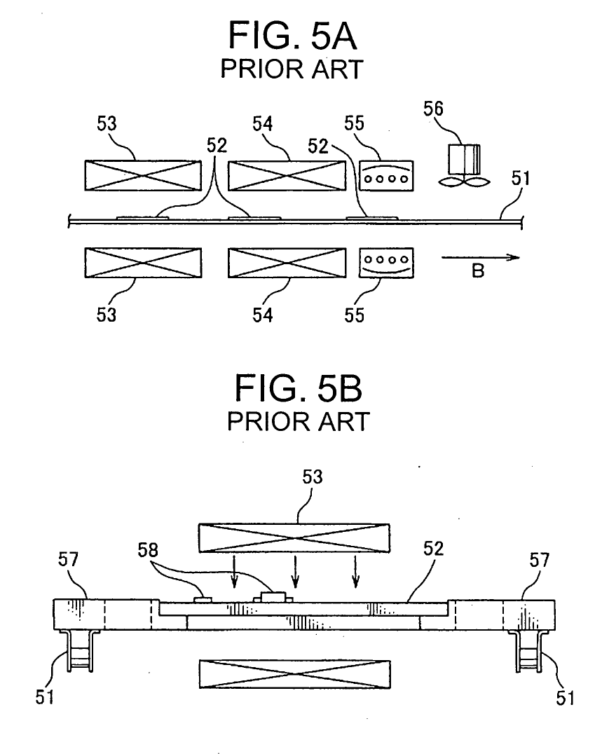

FIG. 1 is a front elevation of the circuit board conveying-soldering apparatus shown in FIG. 2 when viewed from a side indicated by an arrow A in FIG. 2. FIG. 3 shows a plan view of the circuit board 2 shown in FIG. 2 with the upper palette removed. Note that the side indicated by the arrow A is defined as a front side and the opposite side as a rear side in FIG. 2.

As shown in FIG. 1, a connector (indicated by the sign 5 for simplicity) is provided upright at the center of the front side of an upper surface 2b of the circuit board 2. The connector includes a thin oblong connector housing 5 made of an insulating colored synthetic resin, and a plurality of vertically extending pin-shaped terminals 11 are aligned and accommodated in the connector housing 5. The connector housing 5 is secured for example by a screw to the circuit board 2. A lower end 11a of the pin-shaped terminal 11 is passed through a throughhole (not shown) of the circuit board 2 and is slightly exposed out of an underside of the circuit board 2 to an outside. An electrically conducting film surface is applied to the inner surface of the throughhole. The electrically conducting film surface continues to the printed wiring (not shown) of the lower surface 2b, reaching a metal core (not shown) of an intermediate layer of the circuit board.

An upper surface 5a of the connector housing 5 is close to and covered by the protecting portion 17 of the upper palette 4 so as to be protected against the light and heat of the light source 16. Since each of the terminals 11 has to be soldered on and connected to the circuit board 2, two openings (left opening 22 and light opening 23) of the upper palette 4 extend in a vertical direction through a body of the upper palette 4 such that front-ends 22a and 23a of the each of the openings 22 and 23 are positioned close to the a rear-end of the connector housing 5. The circuit wiring in the neighborhood of the connector housing 5 is preheated by the light source 16 and thus the pin-shaped terminals 11 are effectively preheated. In combination with the warm air from the lower side in FIG. 6B, increased preheating temperature can be readily obtained. The protecting portions 17 to 21 of the upper palette 4 are not members specifically attached to the upper palette 4 but plate-shaped walls in one piece with the upper palette 4.

Also, oblong and low-profiled connector housings 6 and 7 made of electrically insulating colored synthetic resin are disposed at right and left sides of the circuit board 2. The pin-shaped or tab-shaped one end of horizontal electrical contacts (not shown) of a plurality of terminals 12 curved in a shape of an L are accommodated in the connector housings juxtaposedly and in two (i.e., upper and lower) rows. The other vertical board-connecting portions 12a of the terminals 12 are passed downward is through the throughhole of the circuit board 2 and slightly protrude out of the lower surface 2a of the circuit board 2 to be exposed to the outside.

The right and left connector housings 6 and 7 made of the colored synthetic resin are covered by the right and left protecting portions 18, 19 of the upper palette 4, and are protected from the light and heat of the light source 16. Thus, the temperature of the light source 16 can be increased compared with a conventional light source shown in FIG. 6 so that the preheating time is shortened. This also applies to the front-side connector housing 5. The connector housings 6 and 7 are fixed for example by screws to the upper surface 2b of the circuit board 2.

The right and left openings 22 and 23 of the upper palette 4 is configured to register with the terminals 12 horizontally extending out of the right and left connector housings 6 and 7 over the circuit board 2, respectively, so that the circuit board 2 and the terminals 12 can be preheated by the light source 16. Also, the connecting portion 12a of the terminal 12 that connects the connector housings 6 and 7 to the circuit board 2 and a portion 2b of the circuit board 2 in the neighborhood thereof are preheated together by the light source 16, and thus the soldered connection of the terminals 12 to the circuit board 2 is enhanced.

Oblong openings 25 are cut out at the right and left ends of the upper palette 4 along ends 6a and 7a of the right and left connector housings 6 and 7, the ends 6a and 7a used to connect corresponding mating connectors. Since the openings 25 are formed close to the connector housings 6 and 7, respectively, and accordingly close to the circuit board 2, the circuit board 2 can be intensively by the light source 16.

A block portion 8 in an oblong rectangular shape is provided at the rear side (i.e., the lower side in FIG. 2) of the circuit board 2. The block portion 8 is a component made of electrically insulating colored synthetic resin. A plurality of horizontally extending clamp terminals (including a body and a pair of clamping pieces) 13 for fuse (electrical component) connection are arranged and juxtaposed to each other at a narrow pitch on an upper surface of the block portion 8. A stem of the clamp terminal 13 is in one piece with and continues to a first vertical portion 13a extending downward. The first vertical portion 13a passes through the block portion 8. The first vertical portion 13a may continue to horizontal elongated bus bars 14. The bus bar 14 passes over the colored-resin components including relays 10 and horizontal portion (for simplicity represented by the sign 12) of the right and left terminals 12, bends downward at the stem's side, and continues integrally to a second vertical portion, i.e., a pin-shaped portion 14a connected to the circuit board 2. The board-connecting portion 14a passes through the throughhole of the circuit board 2 and slightly projects from the lower surface 2a of the circuit board 2.

The clamp terminal 13 has the pair of (i.e., right and left) clamping pieces 13b. The clamp terminals 13 are arranged in two rows in the block portion 8. The lower-row clamp terminals 13 are bent in an L shape. Its vertical pin-shaped board-connecting portion (not shown) is passed through the block portion 8 and inserted into the throughhole of the circuit board 2. A pair of (i.e., upper and lower) tab terminals of the blade-shaped fuse (an electrical component not shown) are clamped and connected by means of the clamp terminals 13.

Corresponding to the upper-row clamp terminal 13, a pair of oblong openings 24, 24 (on a front side and a rear side) are provided on a rear portion of the upper palette 4. A plate portion 21 is formed on the upper palette 4 and between the front-side and rear-side openings 24 and 24′. The plate portion 21 has a pressing member 15 configured to press the terminal 13 and the block portion 8. The clamp terminals 13 are exposed directly underneath the front and rear openings 24 and 24′. The rear-side opening 24′ is formed on a rear-end-side of the upper palette 4. The lower-row clamp terminals 13 are exposed out of the rear-side opening 24′ so as to be capable of receiving light beam 16a emitted by the light source 16.

Since the upper surface of the block portion 8 is covered by the upper clamp terminals 13, a protecting portion in most cases does not need to be provided on the upper palette 4. Nevertheless, the central portion of the block portion 8 is covered by the oblong-plate-shaped protecting portion (that blocks the light source) 21 and thus protection from the light source 16 is in fact provided.

The board-connecting portions 14a of the bus bars 14 that continue to the clamp terminals 13 to the right side and left side of the densely arranged clamp terminals 13 are positioned directly underneath the right and left openings 22 and 23 of the upper palette 4, respectively, and exposed along with the terminals 12 of the right and left connectors 6 and 7 and the circuit wirings 2b in the neighborhood thereof to the light beam and thermal radiation by the light source 16. The bus bars 14 that extend on the central portion of the circuit board 2 is covered by the central protecting portion 20 that blocks the light beam and thermal radiation of the light source, the central protecting portion 20 being provided between the right opening 22 and the left opening 23 of the upper palette 4 so that the colored-resin components 9, 10 such as a relay (strictly speaking, the colored-resin component is an outer insulating case of electrical components such as a relay) can be protected from the light beams irradiated by the light source 16 and its thermal radiation.

Since the plurality of clamp terminals 13 are exposed to the outside via the openings 24 and 24′, each clamp terminal 13 is preheated by the light beams irradiated by the light source 16, and the bus bars 14 and the board-connecting portions 14a thereof that continue to the clamp terminals 13 are preheated by heat transfer. Although the bus bars 14 are covered by the protecting portion 20 of the upper palette 4, the bus bars 14 under the protecting portion 20 can be preheated indirectly. In order to ensure sufficient preheating performance, it is preferable that the lower-row clamp terminals 13 are preheated by the hot air applied from below.

The right-wing and left-wing bus bars 14 and its board-connecting portions 14a are exposed to the outside along with the circuit wirings 2b via the right and left openings 22, 23 of the upper palette 4. Accordingly, the bus bars 14 and their board-connecting portions 14a are directly preheated by the light beams irradiated by the light source 16 and thus the circuit board 2 can be efficiently preheated, so that the soldered connection (or solderability) of the components to the circuit board 2 is improved along with facilitated solder rise in the throughhole and improved solder wettability.

FIG. 4 shows the circuit board conveying-soldering apparatus and the method of preheating effectuated by the same according to the second embodiment of the present invention. The circuit board 2 and the components 5 to 14 are the same as those shown in FIGS. 1 and 2 and accordingly the reference numerals in FIG. 4 refer to the same components shown in FIGS. 1 and 2, detailed explanation of which is not described at length for simplicity.

Although the board-conveying-soldering apparatus 1′ has the same configuration as shown in FIGS. 1 and 2, the upper palette 4′ is not made of synthetic resin but made of a metal material such as aluminum that reflects the light beams of the light source 16, so that, the oblique light beam 16a from the light source 16 indicated by the arrow 16b are reflected by the inner surfaces 22a to 22c, 23a to 23c, 24a, and 24b of the openings 22 to 24 of the upper palette 4′ (see FIG. 2) in an oblique downward direction and the reflected light beams 16b are applied to the circuit board 2, thus the preheating of the circuit board 2 is further promoted.

As indicated by the vertical arrows 16a, and as in a similar manner as in FIG. 1, the circuit board 2 is not only directly irradiated with the light beams and heat of the light source 16 through the openings 22 to 24, but also indirectly by the oblique light beams coming in from the light source 16 and traveling through the openings. By virtue of the light beams 16a directly irradiating from the light source 16 and the indirect oblique irradiating light 16b that has been reflected off the openings' inner surfaces 22a to 22c, 23a to 23c, 24a, and 24b, the circuit board 2 can be preheated more effectively in a shorter period of time than in the case shown in FIG. 1. Irradiation of light beams by the light source 16 for a given unit time will increase the preheating temperature more intensively for the circuit board 2 shown in FIG. 4 than in the case shown in FIG. 1 (temperature rise is accelerated). It should be noted that a target temperature the preheating target temperature in a case of the apparatus shown in FIG. 1 is also valid in the apparatus according to the second embodiment.

Advantageously, the right and left terminals 12 of the circuit board 2 (see FIG. 2), its vertical pin-shaped board-connecting portions 12a and the circuit wirings 2b in the neighborhood thereof, the rear-side clamp terminals 13 (FIG. 2), and the bus bars 14 (FIG. 2) are to be irradiated by the light beams 16b reflected off the openings' inner surfaces 22a to 22c, 23a to 23c, 24a, and 24b. Since the second embodiment only differs from the first embodiment shown in FIG. 2 in that the upper palettes 4 and 4′ are made of different materials, the configuration of the circuit board conveying and soldering apparatus according to the second embodiment is explained hereunder with reference to FIG. 2.

The right and left inner surfaces 22b and the front and rear inner surfaces 22a, and 22c of the right openings 22 of the upper palette 4′ and likewise the right and left inner surfaces 23b and the front and rear inner surfaces 23a and 23c of the left opening 23 of the upper palette 4′ reflect the oblique light beams 16a of the light source 16 in the oblique downward direction, so that the right and left terminals 12, the bus bars 14 and their board-connecting portions 12a, 14a as well as the wirings 2b in the neighborhood thereof are irradiated with the directly applied light beams and the reflected light beams. Also, the front and rear surfaces 24a and the right and left inner surfaces 24b of the rear opening 24 of the upper palette 4′ and likewise the front and rear surfaces 24′a and the right and left inner surfaces 24′b of the rear opening 24′ of the upper palette 4′ reflect the oblique incoming light beams 16a to the oblique outgoing direction, so that the clamp terminals 13 and the circuit wirings 2b in the neighborhood thereof are irradiated with the light beams 16a.

In the second embodiment shown in FIG. 4, the inner surfaces 22a to is 24′b of the openings 22 to 24′ extend linearly and vertically. However, the inner surfaces 22a to 24′b of the openings 22 to 24′ may be tapered or inversely-tapered. In these cases, an angle of inclination of the inner surfaces 22a to 24′b of the openings 22 to 24′ may be defined such that the light beams 16a emitted by the light source 16 can be reflected toward and applied to the portions intended to be solder-connected such as the circuit board 2 and the terminals 12 and 13.

Also, in the second embodiment shown in FIG. 4, the upper palette 4′ as such is formed of the metallic material having a specular or light reflective surface. However, the upper palette 4′ may be made of synthetic resin as shown in FIG. 1 and only the inner surfaces 22a to 24′b of the openings 22 to 24′ may be formed of a metal plate that reflects light or of a metallic foil (not shown).

Having now fully described the preferred embodiment of the present invention, it is clear that the descriptions and explanation contained herein are only cited by way of example rather than limitation, and therefore the present invention can be effectuated with modification and variation without departing from the scope and sprit of the present invention.

What is claimed is:

1. A circuit board conveying and soldering apparatus comprising:
(a) a preheating light source that emits a light beam downward for preheating of a circuit board and components provided thereupon;
(b) a lower palette on which the circuit board and the components provided thereupon are placed; and
(c) an upper palette that is provided beneath the light source and above the lower palette, and is configured to hold the circuit board and the components provided thereupon placed on the lower palette, the upper palette including
a protecting portion that is opposed to a region of the circuit board on which a colored-resin component is provided, and is configured to prevent a light beam of the preheating light source from directly reaching the colored-resin component on the circuit board, and
a plurality of openings that is opposed to a region of the circuit board on which no colored-resin component is provided, and is configured to allow the light beam of the preheating light source to directly reach the region of the circuit board on which no colored resin-component is provided.

2. The circuit board conveying and soldering apparatus of claim 1, wherein at least one of the openings of the upper palette registers with at least one of terminals that are disposed on the circuit board so as to be soldered on and connected to the circuit board.

3. The circuit board conveying and soldering apparatus of claim 2, wherein at least one of the openings registers with the terminal extending out of a connector housing, the connector housing being the colored-resin component provided on the circuit board.

4. The circuit board conveying and soldering apparatus of claim 3, wherein at least one of the openings registers with the terminal that connects an electrical component to the circuit board, and a bus bar formed in one piece with the terminal is soldered on and connected to the circuit board.

5. The circuit board conveying and soldering apparatus of claim 4, wherein at least one of the openings registers with the bus bar extending on the circuit board.

6. A circuit board conveying and soldering apparatus comprising:
(a) a preheating light source that emits a light beam downward for preheating of a circuit board and components provided thereupon;
(b) a lower palette on which the circuit board and the components provided thereupon are placed; and
(c) an upper palette that is provided beneath the light source and above the lower palette, and is configured to hold the circuit board and the components provided thereupon placed on the lower palette, the upper palette including
a protecting portion that is opposed to a region of the circuit board on which a colored-resin component is provided, and is configured to prevent a light beam of the preheating light source from directly reaching the colored-resin component on the circuit board, and
a plurality of openings that is opposed to a region of the circuit board on which no colored-resin component is provided, and is configured to allow the light beam of the preheating light source to directly reach the region of the circuit board on which no colored resin-component is provided, an inner surface of the opening being made of a light reflective material so that the incoming light beam is reflected off the inner surface in a downward direction.

7. The circuit board conveying and soldering apparatus of claim 6, wherein at least one of the openings of the upper palette registers with at least one of terminals that are disposed on the circuit board so as to be soldered on and connected to the circuit board.

8. The circuit board conveying and soldering apparatus of claim 7, wherein at least one of the openings registers with the terminal extending out of a connector housing, the connector housing being the colored-resin component provided on the circuit board.

9. The circuit board conveying and soldering apparatus of claim 8, wherein at least one of the openings registers with the terminal that connects an electrical component to the circuit board, and a bus bar formed in one piece with the terminal is soldered on and connected to the circuit board.

10. The circuit board conveying and soldering apparatus of claim 9, wherein at least one of the openings registers with the bus bar extending on the circuit board.

11. A circuit board conveying and soldering apparatus comprising:
(a) a preheating light source that emits a light beam downward for preheating of a circuit board and components provided thereupon;
(b) a lower palette on which the circuit board and the components provided thereupon are placed; and
(c) an upper palette that is provided beneath the light source and above the lower palette, made of a light reflective material so that an incoming light beam is reflected off the inner surface in a downward direction, and configured to hold the circuit board and the components provided thereupon placed on the lower palette, the upper palette including
a protecting portion that is opposed to a region of the circuit board on which a colored-resin component is provided, and is configured to prevent a light beam of the preheating light source from directly reaching the colored-resin component on the circuit board, and
a plurality of openings that is opposed to a region of the circuit board on which no colored-resin component is provided, and is configured to allow the light beam of the preheating light source to directly reach the region of the circuit board on which no colored resin-component is provided.

12. The circuit board conveying and soldering apparatus of claim 11, wherein at least one of the openings of the upper palette registers with at least one of terminals that are disposed on the circuit board so as to be soldered on and connected to the circuit board.

13. The circuit board conveying and soldering apparatus of claim 12, wherein at least one of the openings registers with the terminal extending out of a connector housing, the connector housing being the colored-resin component provided on the circuit board.

14. The circuit board conveying and soldering apparatus of claim 13, wherein at least one of the openings registers with the terminal that connects an electrical component to the circuit board, and a bus bar formed in one piece with the terminal is soldered on and connected to the circuit board.

15. The circuit board conveying and soldering apparatus of claim 14, wherein at least one of the openings registers with the bus bar extending on the circuit board.
